(19) United States
(12) Patent Application Publication
(10) Pub. No.: US 2023/0341773 A1
(43) Pub. Date: Oct. 26, 2023

(54) PHOTORESIST COMPOSITION WITH NOVEL SOLVENT

(71) Applicant: TAIWAN SEMICONDUCTOR MANUFACTURING COMPANY, LTD., Hsinchu (TW)

(72) Inventors: An-Ren ZI, Hsinchu City (TW); Ching-Yu CHANG, Yilang County (TW)

(73) Assignee: TAIWAN SEMICONDUCTOR MANUFACTURING COMPANY, LTD., Hsinchu (TW)

(21) Appl. No.: 17/726,036

(22) Filed: Apr. 21, 2022

(51) Int. Cl. G03F 7/004; G03F 7/20

(52) U.S. Cl. CPC G03F 7/0048; G03F 7/70191

(57) ABSTRACT

A method of manufacturing a semiconductor device includes forming a photoresist layer over a substrate, exposing the photoresist layer to an EUV radiation, and developing the exposed photoresist layer. The photoresist layer has a composition including a solvent mixture and a metal-containing component dissolved in the solvent mixture. The solvent mixture includes a first solvent comprising primary alcohol.

### BACKGROUND

As consumer devices have gotten smaller and smaller in response to consumer demand, the individual components of these devices have necessarily decreased in size as well. Semiconductor devices, which make up a major component of devices such as mobile phones, computer tablets, and the like, have been pressured to become smaller and smaller, with a corresponding pressure on the individual devices (e.g., transistors, resistors, capacitors, etc.) within the semiconductor devices to also be reduced in size.

One enabling technology that is used in the manufacturing processes of semiconductor devices is the use of photolithographic materials. Such materials are applied to a surface of a layer to be patterned and then exposed to an energy that has itself been patterned. Such an exposure modifies the chemical and physical properties of the exposed regions of the photosensitive material. This modification, along with the lack of modification in regions of the photosensitive material that were not exposed, can be exploited to remove one region without removing the other.

However, as the size of individual devices has decreased, process windows for photolithographic processing has become tighter and tighter. As such, advances in the field of photolithographic processing are necessary to maintain the ability to scale down the devices, and further improvements are needed in order to meet the desired design criteria such that the march towards smaller and smaller components may be maintained.

As the semiconductor industry has progressed into nanometer technology process nodes in pursuit of higher device density, higher performance, and lower costs, there have been challenges in reducing semiconductor feature size. Extreme ultraviolet lithography (EUVL) has been developed to form smaller semiconductor device feature size and increase device density on a semiconductor wafer. In order to improve EUVL an increase in wafer exposure throughput is desirable.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1A is a schematic view of an EUV lithography tool with an LPP-based EUV radiation source, in accordance with some embodiments of the present disclosure.

FIG. 1B is a simplified schematic diagram of a detail of an extreme ultraviolet lithography tool according to an embodiment of the disclosure showing the exposure of photoresist coated substrate with a patterned beam of EUV light.

FIG. 2 is a sectional view of a EUV mask constructed in accordance with some embodiments of the present disclosure.

FIGS. 3, 4, 6, and 7 are diagrammatic fragmentary cross-sectional side views of a semiconductor device at various stages of fabrication in accordance with various aspects of the present disclosure.

FIGS. 5A, 5B and 5C show a sequence of operations in FIGS. 3 and 4 in accordance with various aspects of the present disclosure.

FIGS. 8A and 8B show examples of photoresist layer patterning according to embodiments of the disclosure.

FIGS. 9A and 9B show examples of substrate patterning according to embodiments of the disclosure.

FIG. 10 illustrates some examples of the primary alcohol according to embodiments of the disclosure.

FIG. 11 illustrates some examples of the secondary alcohol according to embodiments of the disclosure.

FIG. 12 illustrates some examples of the tertiary alcohol according to embodiments of the disclosure.

FIG. 13A illustrates some examples of the diol according to embodiments of the disclosure.

FIG. 13B illustrates some examples of alcohol with ether group located on the main chain according to embodiments of the disclosure.

FIGS. 14, 15, 16A illustrate perspective views of additional fabrication processes in the formation of a semiconductor device using a substrate in accordance with some embodiments of the present disclosure.

FIGS. 16B, 17, 18 and 19 illustrate cross-sectional views of additional fabrication processes in the formation of a semiconductor device using a substrate in accordance with some embodiments of the present disclosure.

### DETAILED DESCRIPTION

It is to be understood that the following disclosure provides many different embodiments, or examples, for implementing different features of the disclosure. Specific embodiments or examples of components and arrangements are described below to simplify the present disclosure. These are, of course, merely examples and are not intended to be limiting. For example, dimensions of elements are not limited to the disclosed range or values, but may depend upon process conditions and/or desired properties of the device. Moreover, the formation of a first feature over or on a second feature in the description that follows may include embodiments in which the first and second features are formed in direct contact, and may also include embodiments in which additional features may be formed interposing the first and second features, such that the first and second features may not be in direct contact. Various features may be arbitrarily drawn in different scales for simplicity and clarity.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. In addition, the term “made of” may mean either “comprising” or “consisting of.”

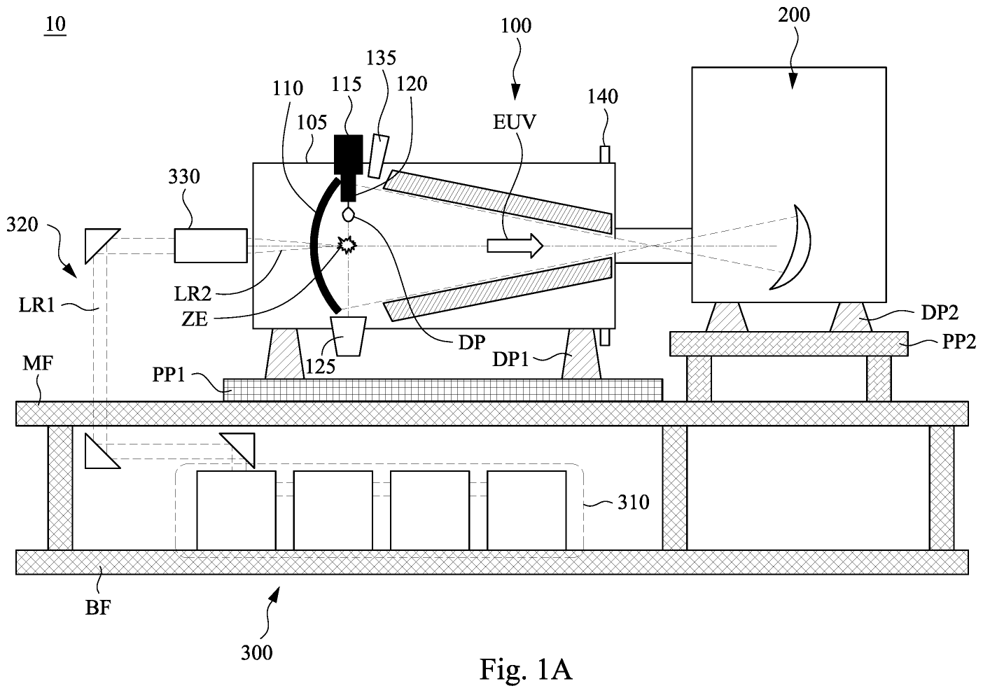

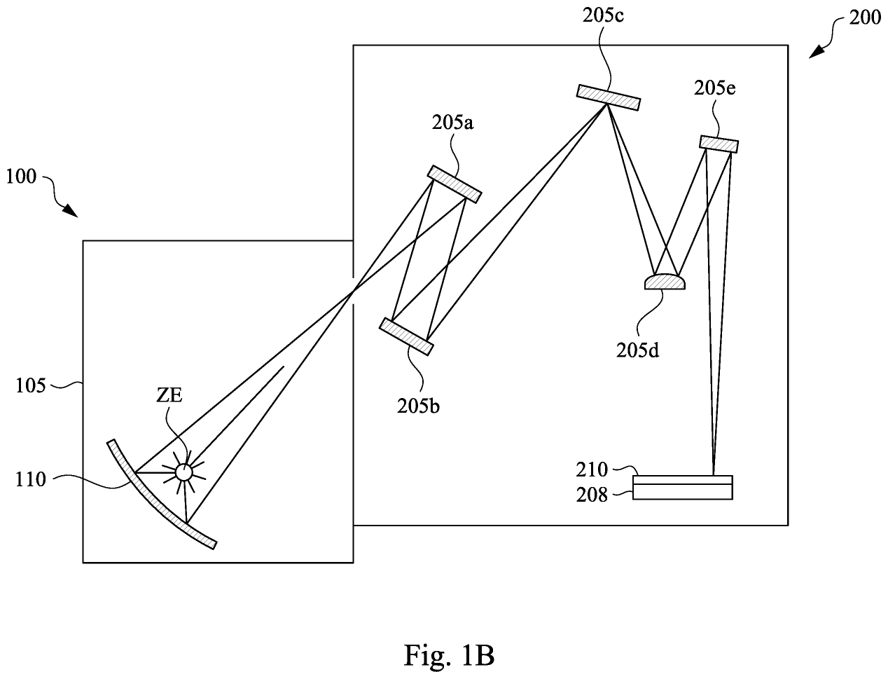

FIG. 1A is a schematic view diagram of an EUV lithography system 10, constructed in accordance with some embodiments. The EUV lithography system 10 may also be generically referred to as a scanner that is configured to perform lithography exposure processes with respective radiation source and exposure mode. The EUV lithography system 10 is designed to expose a photoresist layer by EUV light or EUV radiation. The photoresist layer is a material sensitive to the EUV light. The EUV lithography system 10 employs a radiation source 100 to generate EUV light, such as EUV light having a wavelength ranging between about 1 nm and about 100 nm. In one particular example, the radiation source 100 generates a EUV light with a wavelength centered at about 13.5 nm. Accordingly, the radiation source 100 is also referred to as EUV radiation source 100.

Extreme ultraviolet (EUV) lithography has become widely used due to its ability to achieve small semiconductor device sizes, for example for 20 nanometer (nm) technology nodes. Metal oxide based photoresists, such as tin based coating materials, exhibit good absorption of far ultraviolet light at a 193 nm wavelength and extreme ultraviolet light at a 13.5 nm wavelength, being more efficient than organic polymers in EUV absorptions. Although metal oxide photoresists have nice lithographic patterns, they are sensitive to moisture and high-polarity chemicals and tend to form aggregates, leading to increased defects, adversely affecting the quality of the overall coating.

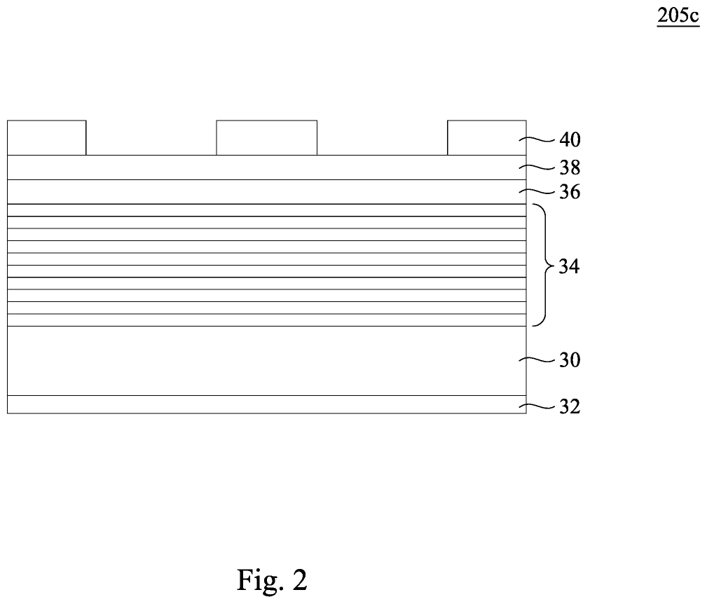

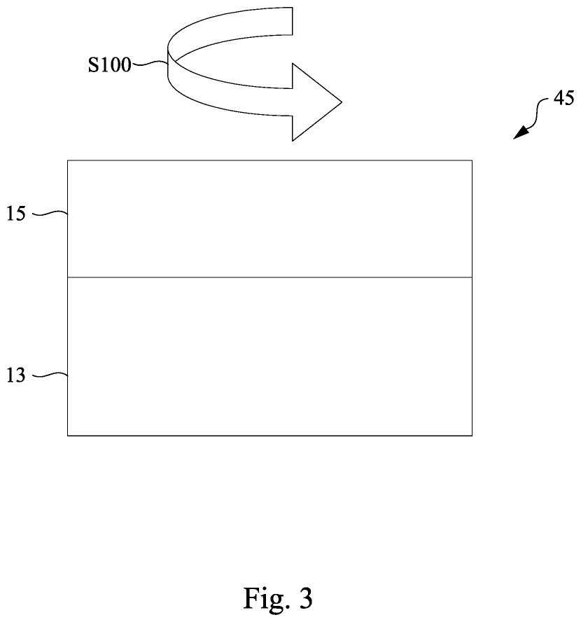

The present disclosure provides a novel photoresist having metal-containing component dissolved in a solvent mixture including primary alcohol. The primary alcohol becomes the ligand of the metal-containing component after they are mixed. The primary alcohol can prevent aggregation of the metal-containing component and thus can enhance dispersion quality thereof. As compared to secondary and tertiary alcohols, the primary alcohol is more resistant to moisture, water, contaminations with high polarity functional group on the equipment which may be left from fabrication. Consequently, the photoresist can be formed with reduced defects. The various aspects of the present disclosure will be discussed below in greater detail with reference to FIGS. 1A-19. First, a EUV lithography system will be discussed below with reference to FIGS. 1A, 1B and 2. Next, the details of the novel photoresist and the lithography process employing the photoresist will be discussed with reference to FIGS. 3-19.

The advanced lithography process, method, and materials described in the current disclosure can be used in many applications, including fin-type field effect transistors (FinFETs), gate-all-around (GAA) FETs. For example, the fins may be patterned to produce a relatively close spacing between features, for which the above disclosure is well suited. In addition, spacers used in forming fins of FinFETs can be processed according to the above disclosure.

To address the trend of the Moore's law for decreasing size of chip components and the demand of higher computing power chips for mobile electronic devices such as smart phones with computer functions, multi-tasking capabilities, or even with workstation power. Smaller wavelength photolithography exposure systems are desirable. Extreme ultraviolet (EUV) photolithography technique uses an EUV radiation source to emit an EUV light ray with wavelength of about 13.5 nm. Because this wavelength is also in the x-ray radiation wavelength region, the EUV radiation source is also called a soft x-ray radiation source. The EUV light rays emitted from a laser-produced plasma (LPP) are collected by a collector mirror and reflected toward a patterned mask.

FIG. 1A is a schematic view of an EUV lithography tool with an LPP-based EUV radiation source, in accordance with some embodiments of the present disclosure. The EUV lithography system includes an EUV radiation source 100 to generate EUV radiation, an exposure device 200, such as a scanner, and an excitation laser source 300. As shown in FIG. 1A, in some embodiments, the EUV radiation source 100 and the exposure device 200 are installed on a main floor MF of a clean room, while the excitation laser source 300 is installed in a base floor BF located under the main floor MF. Each of the EUV radiation source 100 and the exposure device 200 are placed over pedestal plates PP1 and PP2 via dampers DP1 and DP2, respectively. The EUV radiation source 100 and the exposure device 200 are coupled to each other by a coupling mechanism, which may include a focusing unit.

The EUV lithography tool is designed to expose a resist layer to EUV light (also interchangeably referred to herein as EUV radiation). The resist layer is a material sensitive to the EUV light. The EUV lithography system employs the EUV radiation source 100 to generate EUV light, such as EUV light having a wavelength ranging between about 1 nm and about 100 nm. In one particular example, the EUV radiation source 100 generates an EUV light with a wavelength centered at about 13.5 nm. In the present embodiment, the EUV radiation source 100 utilizes a mechanism of laser-produced plasma (LPP) to generate the EUV radiation.

The exposure device 200 includes various reflective optic components, such as convex/concave/flat mirrors, a mask holding mechanism including a mask stage, and wafer holding mechanism. The EUV radiation EUV generated by the EUV radiation source 100 is guided by the reflective optical components onto a mask secured on the mask stage. In some embodiments, the mask stage includes an electrostatic chuck (e-chuck) to secure the mask.

FIG. 1B is a simplified schematic diagram of a detail of an extreme ultraviolet lithography tool according to an embodiment of the disclosure showing the exposure of photoresist coated substrate 210 secured on a substrate stage 208 of the exposure device 200 with a patterned beam of EUV light. The exposure device 200 is an integrated circuit lithography tool such as a stepper, scanner, step and scan system, direct write system, device using a contact and/or proximity mask, etc., provided with one or more optics 205a, 205b, for example, to illuminate a patterning optic 205c, such as a reticle, with a beam of EUV light, to produce a patterned beam, and one or more reduction projection optics 205d, 205e, for projecting the patterned beam onto the photoresist coated substrate 210. A mechanical assembly (not shown) may be provided for generating a controlled relative movement between the photoresist coated substrate 210 and the patterning optic 205c. As further shown in FIG. 2, the EUVL tool includes an EUV radiation source 100 including an EUV light radiator ZE emitting EUV light in a chamber 105 that is reflected by a collector 110 along a path into the exposure device 200 to irradiate the photoresist coated substrate 210.

As used herein, the term “optic” is meant to be broadly construed to include, and not necessarily be limited to, one or more components which reflect and/or transmit and/or operate on incident light, and includes, but is not limited to, one or more lenses, windows, filters, wedges, prisms, grisms, gradings, transmission fibers, etalons, diffusers, homogenizers, detectors and other instrument components, apertures, axicons and mirrors including multi-layer mirrors, near-normal incidence mirrors, grazing incidence mirrors, specular reflectors, diffuse reflectors and combinations thereof. Moreover, unless otherwise specified, the term “optic”, as used herein, is directed to, but not limited to, components which operate solely or to advantage within one or more specific wavelength range(s) such as at the EUV output light wavelength, the irradiation laser wavelength, a wavelength suitable for metrology or any other specific wavelength.

In various embodiments of the present disclosure, the photoresist coated substrate 210 is a semiconductor wafer, such as a silicon wafer or other type of wafer to be patterned. The EUVL tool further includes other modules or is integrated with (or coupled with) other modules in some embodiments.

As shown in FIG. 1A, the EUV radiation source 100 includes a target droplet generator 115 and a collector 110, enclosed by a chamber 105. For example, the collector 110 is a laser-produced plasma (LPP) collector. In various embodiments, the target droplet generator 115 includes a reservoir to hold a source material and a nozzle 120 through which target droplets DP of the source material are supplied into the chamber 105.

In some embodiments, the target droplets DP are metal droplets of tin (Sn), lithium (Li), or an alloy of Sn and Li. In some embodiments, the target droplets DP each have a diameter in a range from about 10 microns (μm) to about 100 μm. For example, in an embodiment, the target droplets DP are tin droplets, having a diameter of about 10 μm to about 100 μm. In other embodiments, the target droplets DP are tin droplets having a diameter of about 25 μm to about 50 μm. In some embodiments, the target droplets DP are supplied through the nozzle 120 at a rate in a range from about 50 droplets per second (i.e., an ejection-frequency of about 50 Hz) to about 50,000 droplets per second (i.e., an ejection-frequency of about 50 kHz).

Referring back to FIG. 1A, an excitation laser LR2 generated by the excitation laser source 300 is a pulse laser. The laser pulses LR2 are generated by the excitation laser source 300. The excitation laser source 300 may include a laser generator 310, laser guide optics 320 and a focusing apparatus 330. In some embodiments, the laser generator 310 includes a carbon dioxide (CO2) or a neodymium-doped yttrium aluminum garnet (Nd:YAG) laser source with a wavelength in the infrared region of the electromagnetic spectrum. For example, the laser generator 310 has a wavelength of about 9.4 μm or about 10.6 μm, in an embodiment. The laser light LR1 generated by the laser generator 310 is guided by the laser guide optics 320 and focused into the excitation laser LR2 by the focusing apparatus 330, and then introduced into the EUV radiation source 100.

In some embodiments, the excitation laser LR2 includes a pre-heat laser and a main laser. In such embodiments, the pre-heat laser pulse (interchangeably referred to herein as the “pre-pulse”) is used to heat (or pre-heat) a given target droplet to create a low-density target plume with multiple smaller droplets, which is subsequently heated (or reheated) by a pulse from the main laser, generating increased emission of EUV light.

In various embodiments, the pre-heat laser pulses have a spot size about 100 μm or less, and the main laser pulses have a spot size in a range of about 150 μm to about 300 μm. In some embodiments, the pre-heat laser and the main laser pulses have a pulse-duration in the range from about 10 ns to about 50 ns, and a pulse-frequency in the range from about I kHz to about 100 kHz. In various embodiments, the pre-heat laser and the main laser have an average power in the range from about 1 kilowatt (kW) to about 50 kW. The pulse-frequency of the excitation laser LR2 is matched with (e.g., synchronized with) the ejection-frequency of the target droplets DP in an embodiment.

The excitation laser LR2 is directed through windows (or lenses) into the zone of excitation ZE in front of the collector 110. The windows are made of a suitable material substantially transparent to the laser beams. The generation of the pulse lasers is synchronized with the ejection of the target droplets DP through the nozzle 120. As the target droplets move through the excitation zone, the pre-pulses heat the target droplets and transform them into low-density target plumes. A delay between the pre-pulse and the main pulse is controlled to allow the target plume to form and to expand to an optimal size and geometry. In various embodiments, the pre-pulse and the main pulse have the same pulse-duration and peak power. When the main pulse heats the target plume, a high-temperature plasma is generated. The plasma emits EUV radiation EUV, which is collected by the collector 110. The collector 110 further reflects and focuses the EUV radiation for the lithography exposing processes performed through the exposure device 200. The droplet catcher 125 is used for catching excessive target droplets. For example, some target droplets may be purposely missed by the laser pulses.

In some embodiments, the collector 110 is designed with a proper coating material and shape to function as a mirror for EUV collection, reflection, and focusing. In some embodiments, the collector 110 is designed to have an ellipsoidal geometry. In some embodiments, the coating material of the collector 110 is similar to the reflective multilayer of the EUV mask. In some examples, the coating material of the collector 110 includes a ML (such as a plurality of Mo/Si film pairs) and may further include a capping layer (such as Ru) coated on the ML to substantially reflect the EUV light. In some embodiments, the collector 110 may further include a grating structure designed to effectively scatter the laser beam directed onto the collector 110. For example, a silicon nitride layer is coated on the collector 110 and is patterned to have a grating pattern.

In the present disclosure, the terms mask, photomask, and reticle are used interchangeably. In the present embodiment, the patterning optic 205c is a reflective mask 205c. The reflective mask 205c also includes a reflective ML deposited on the substrate. The ML includes a plurality of film pairs, such as molybdenum-silicon (Mo/Si) film pairs (e.g., a layer of molybdenum above or below a layer of silicon in each film pair). Alternatively, the ML may include molybdenum-beryllium (Mo/Be) film pairs, or other suitable materials that are configurable to highly reflect the EUV light.

The mask 205c may further include a capping layer, such as ruthenium (Ru), disposed on the ML for protection. The mask 205c further includes an absorption layer deposited over the ML. The absorption layer is patterned to define a layer of an integrated circuit (IC), the absorber layer is discussed below in greater detail according to various aspects of the present disclosure. Alternatively, another reflective layer may be deposited over the ML and is patterned to define a layer of an integrated circuit, thereby forming a EUV phase shift mask.

The mask 205c and the method making the same are further described in accordance with some embodiments. In some embodiments, the mask fabrication process includes two operations: a blank mask fabrication process and a mask patterning process. During the blank mask fabrication process, a blank mask is formed by deposing suitable layers (e.g., reflective multiple layers) on a suitable substrate. The blank mask is then patterned during the mask patterning process to achieve a desired design of a layer of an integrated circuit (IC). The patterned mask is then used to transfer circuit patterns (e.g., the design of a layer of an IC) onto a semiconductor wafer. The patterns can be transferred over and over onto multiple wafers through various lithography processes. A set of masks is used to construct a complete IC.

One example of the reflective mask 205c is shown in FIG. 2. The reflective mask 205c in the illustrated embodiment is a EUV mask, and includes a substrate 30 made of a LTEM. The LTEM material may include TiO₂ doped SiO₂, and/or other low thermal expansion materials known in the art. In some embodiments, a conductive layer 32 is additionally disposed under on the backside of the LTEM substrate 30 for the electrostatic chucking purpose. In one example, the conductive layer 32 includes chromium nitride (CrN), though other suitable compositions are possible.

The reflective mask 205c includes a reflective multilayer (ML) structure 34 disposed over the LTEM substrate 30. The ML structure 34 may be selected such that it provides a high reflectivity to a selected radiation type/wavelength. The ML structure 34 includes a plurality of film pairs, such as Mo/Si film pairs (e.g., a layer of molybdenum above or below a layer of silicon in each film pair). Alternatively, the ML structure 34 may include Mo/Be film pairs, or any materials with refractive index difference being highly reflective at EUV wavelengths.

Still referring to FIG. 2, the EUV mask 205c also includes a capping layer 36 disposed over the ML structure 34 to prevent oxidation of the ML. The EUV mask 205c may further include a buffer layer 38 disposed above the capping layer 36 to serve as an etching-stop layer in a patterning or repairing process of an absorption layer, which will be described later. The buffer layer 38 has different etching characteristics from the absorption layer disposed thereabove. The buffer layer 38 includes ruthenium (Ru), Ru compounds such as RuB, RuSi, chromium (Cr), chromium oxide, and chromium nitride in various examples.

The EUV mask 205c also includes an absorber layer 40 (also referred to as an absorption layer) formed over the buffer layer 38. In some embodiments, the absorber layer 40 absorbs the EUV radiation directed onto the mask. In various embodiments, the absorber layer may be made of tantalum boron nitride (TaBN), tantalum boron oxide (TaBO), or chromium (Cr), Radium (Ra), or a suitable oxide or nitride (or alloy) of one or more ofthe following materials: Actium, Radium, Tellurium, Zinc, Copper, and Aluminum.

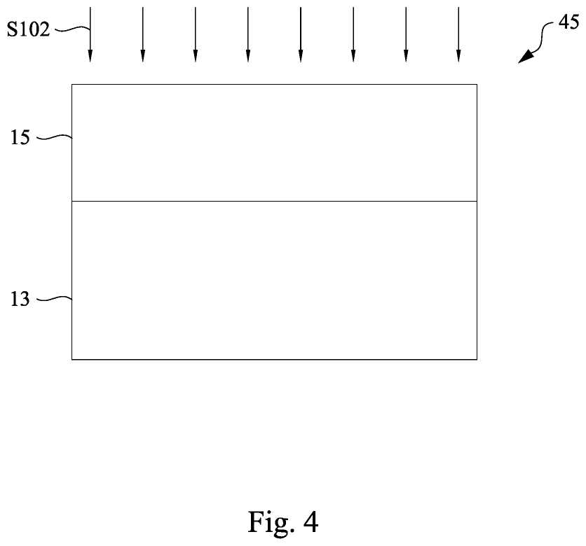

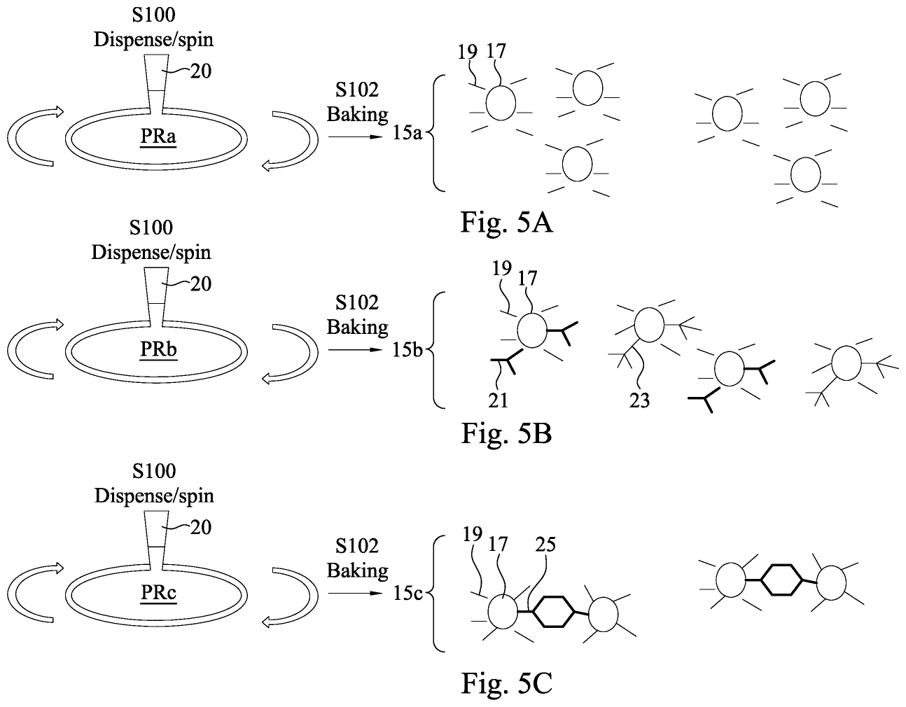

FIGS. 3, 4, 6 and 7 are diagrammatic fragmentary cross-sectional side views of a semiconductor device 45 at various stages of fabrication in accordance with various aspects of the present disclosure. FIGS. 5A, 5B and 5C show a sequence of operations in FIGS. 3 and 4 in accordance with various aspects ofthe present disclosure. In some embodiments, the semiconductor device 45 may include an integrated circuit (IC) chip, system on chip (SoC), or portion thereof, and may include various passive and active microelectronic devices such as resistors, capacitors, inductors, diodes, metal-oxide semiconductor field effect transistors (MOSFET), complementary metal-oxide semiconductor (CMOS) transistors, bipolar junction transistors (BJT), laterally diffused MOS (LDMOS) transistors, high power MOS transistors, or other types of transistor.

Reference is made to FIG. 3. A photoresist layer 15 is coated on a surface of a layer to be patterned (or target layer) or a substrate in an operation S100. For example, the semiconductor device 45 includes a substrate 13 is illustrated. In some embodiments, the substrate 13 is a silicon substrate doped with a p-type dopant such as boron (for example a p-type substrate). Alternatively, the substrate 13 could be another suitable semiconductor material. For example, the substrate 13 may be a silicon substrate that is doped with an n-type dopant such as phosphorous or arsenic (an n-type substrate). The substrate 13 could include other elementary semiconductors such as germanium and diamond. The substrate 13 could optionally include a compound semiconductor and/or an alloy semiconductor. Further, the substrate 13 could include an epitaxial layer (epi layer), may be strained for performance enhancement, and may include a silicon-on-insulator (SOI) structure.

In some embodiments, the substrate 13 is substantially conductive or semi-conductive. The electrical resistance may be less than about 10³ ohm-meter. In some embodiments, the substrate 13 contains metal, metal alloy, or metal nitride/sulfide/selenide/oxide/silicide with the formula MXa, where M is a metal, and X is N, S, Se, O, Si, and where “a” is in a range from about 0.4 to 2.5. For example, the substrate 48 may contain Ti, Al, Co, Ru, TiN, WN₂, or TaN.

In some other embodiments, the substrate 13 contains a dielectric material with a dielectric constant in a range from about 1 to about 40. In some other embodiments, the substrate 13 contains Si, metal oxide, or metal nitride, where the formula is MX_{b}, wherein M is a metal or Si, and X is N or O, and wherein “b” is in a range from about 0.4 to 2.5. For example, the substrate 13 may contain SiO₂, silicon nitride, aluminum oxide, hafnium oxide, or lanthanum oxide.

The photoresist layer 15 may be formed by a spin-coating process. The photoresist layer 15 has a composition including a solvent mixture and a metal-containing component dissolved in the solvent mixture. In some embodiments, the metal-containing component is an organometallic compound or precursor, such as transition metal complexes characterized with coordination numbers that range from 1 to 12. When exposed to actinic radiation, the photoresist layer 15 undergoes one or more chemical reactions causing a change in solubility in a developer composition. In some embodiments, the metal-containing component has a transition metal including zirconium, manganese, aluminum, vanadium, titanium, chromium, manganese, iron, cobalt, nickel, copper, zinc, gallium, germanium, arsenic, molybdenum, ruthenium, rhodium, palladium, silver, cadmium, indium, tin, antimony, tellurium, iodine, thulium, hafnium, tantalum, tungsten, rhenium, osmium, iridium, platinum, gold, mercury, thallium, lead, bismuth, manganese, nickel, palladium, platinum, iron, antimony, tellurium, tin, cobalt, bismuth, chromium, copper.

The solvent mixture of the photoresist layer 15 includes a first solvent and a second solvent different from the first solvent. For example, the first solvent is primary alcohol. The primary alcohol can prevent aggregation of the metal-containing component and thus can enhance dispersion quality thereof. By mixing the metal-containing component and the solvent mixture, the primary alcohol becomes the ligand of the metal-containing component. As compared to secondary alcohol and tertiary alcohol, the primary alcohol has a higher environmental stability. For example, the primary alcohol is more resistant toward moisture, water, contaminations with high polarity functional group on the equipment which may be left from fabrication.

Primary alcohol has an —OH group attached to a carbon atom which is bonded to another carbon atom and have the general formula (I):

R¹—COH (I),

wherein R¹ is a linear or branched C1-C8 alkyl group. In some embodiments, the primary alcohol may be represented by the general formula (II) or the general formula (III):

R¹—O—COH (II),

R¹—O—R¹—COH (III).

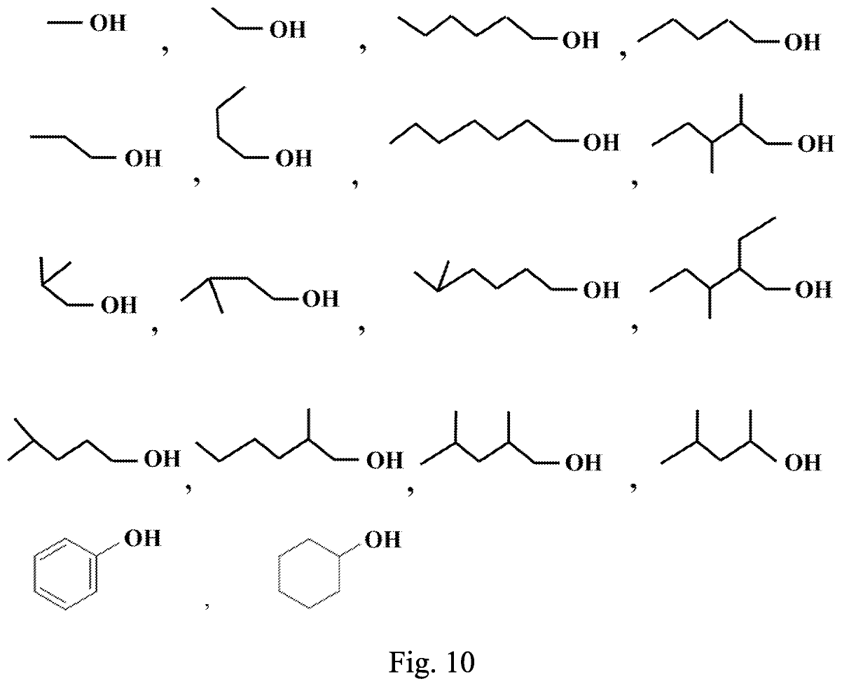

FIG. 10 illustrates some examples of the primary alcohol according to embodiments of the disclosure. The primary alcohol has a carbon number of 8 or less. In other words, the primary alcohol is a C1-C8 compound. If the carbon number of the primary alcohol is too large (e.g., greater than 8), the metal-containing component may have poor solubility in the primary alcohol. The second solvent may be Propylene glycol methyl ether acetate (PGMEA), propylene glycol monomethyl ether (PGME), 1-Ethoxy-2-propanol (PGEE), Gamma-Butyrolactone (GBL), Cyclohexanone (CHN), Ethyl lactate (EL), Methanol, Ethanol, Propanol, n-Butanol, Acetone, Dimethylformamide (DMF), Isopropyl alcohol (IPA), Tetrahydrofuran (THF), Methyl Isobutyl Carbinol (MIBC), (n-butyl acetate (nBA), 2-heptanone (MAK), the like, or a combination thereof. In some embodiments where the first solvent is primary alcohol, an amount of the first solvent falls within a range from about 50% to about 100% based on the weight of the solvent mixture while the second solvent is controlled at about 50% or less than 50% based on the weight ofthe solvent mixture. If the amount of the first solvent is excessively small (e.g., far lower than 50%), a line width roughness (LWR) and defects in the photoresist layer 15 could not be improved effectively.

The vapor pressure of the first solvent is greater than 0.2 kPa at 20 ° C., which allows rapid removal of the solvent mixture by baking. If the vapor pressure ofthe first solvent is excessively small (e.g., far lower than 0.2 kPa), the first solvent may remain on the substrate 13 easily, causing worse line width roughness (LWR) and increased defects. The first solvent has a boiling point of less than 300° C. and greater than 25° C., and a melting point of less than 23° C. If the boiling point of the first solvent is excessively large (e.g., far greater than 300° C.), the first solvent cannot be removed by resist baking, causing worse line width roughness (LWR) and increased defects. If the melting point of the first solvent is excessively large (e.g., far greater than 23° C.), the photoresist layer 15 cannot be formed by spin-coating process.

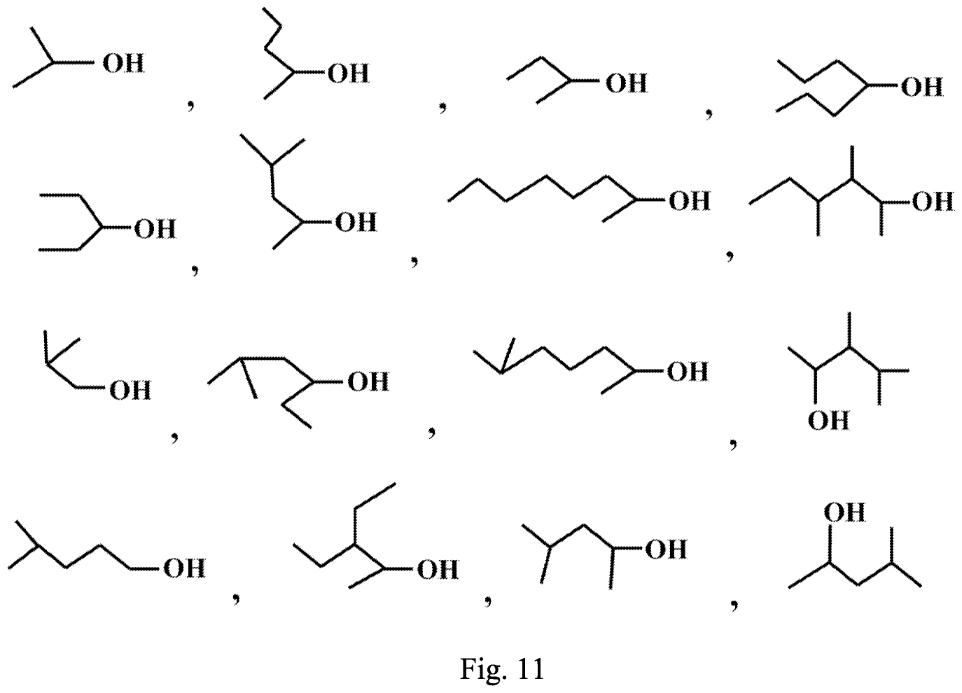

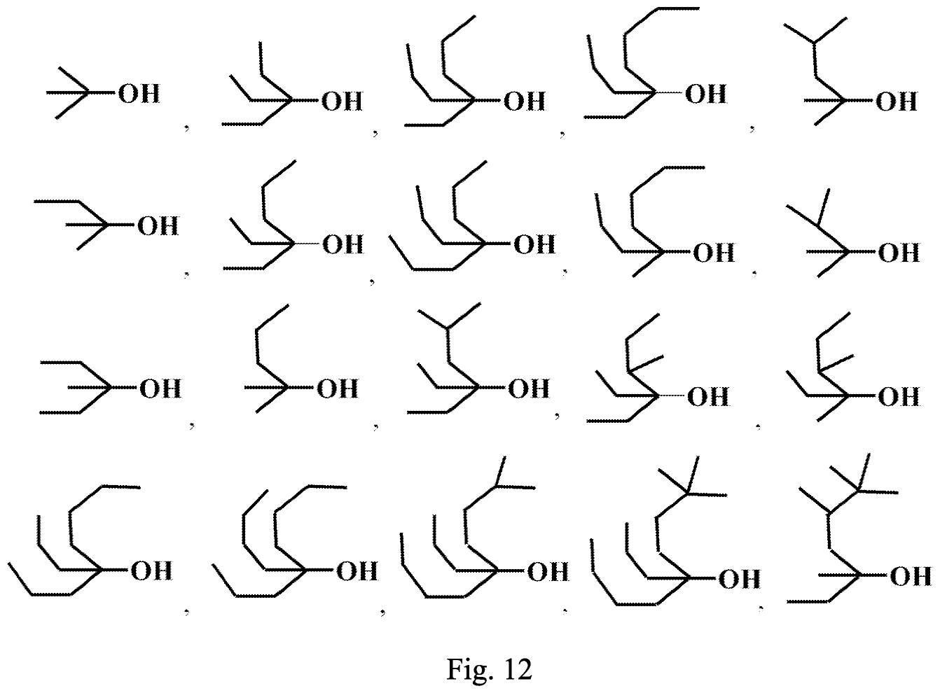

In some embodiments, the solvent mixture further includes a third solvent. The third solvent is different from both of the first solvent and the second solvent. For example, the third solvent is selected from a group consisting of secondary alcohol and tertiary alcohol. Secondary alcohols have an —OH group attached to a carbon atom that is bonded to two other carbon atoms. In particular, the secondary alcohol have the general formula (IV):

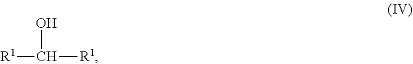

wherein each R¹ is selected independently from the group of linear or branched alkyl group. FIG. 11 illustrates some examples of the secondary alcohol according to embodiments of the disclosure. The secondary alcohol has a carbon number of less than 15 in some embodiments. If the carbon number of the secondary alcohol is too large (e.g., greater than 15), the metal-containing component may have poor solubility in the secondary alcohol.

Tertiary alcohols have an —OH group attached to a carbon atom that is bonded to three other carbon atoms. In particular, the tertiary alcohols have the general formula (V):

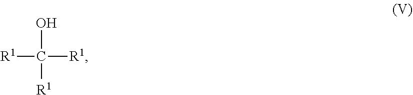

wherein each R¹ is selected independently from the group of linear or branched alkyl group. FIG. 11 illustrates some examples of the tertiary alcohol according to embodiments of the disclosure. The tertiary alcohol has a carbon number of less than 15 in some embodiments.

In some embodiments where the first solvent is primary alcohol and the third solvent is selected from a group consisting of secondary alcohol and tertiary alcohol, an amount of the first solvent falls within a range from about 50% to about 100% based on the weight of the solvent mixture while an amount of a sum of the second solvent and the third solvent is controlled at about 50% or less than 50% based on the weight of the solvent mixture. If the amount of the first solvent is excessively small (e.g., far lower than 50%), the line width roughness (LWR) and defects in the photoresist layer 15 could not be improved effectively.

In some embodiments where the third solvent is selected from a group consisting of secondary alcohol and tertiary alcohol, the vapor pressure of a sum of the first solvent and the third solvent is greater than 0.2 kPa at 20° C., which allows rapid removal of the solvent mixture by baking. The sum of the first solvent and the third solvent has a boiling point of less than 300° C. and greater than 25° C., and a melting point of less than 23° C.

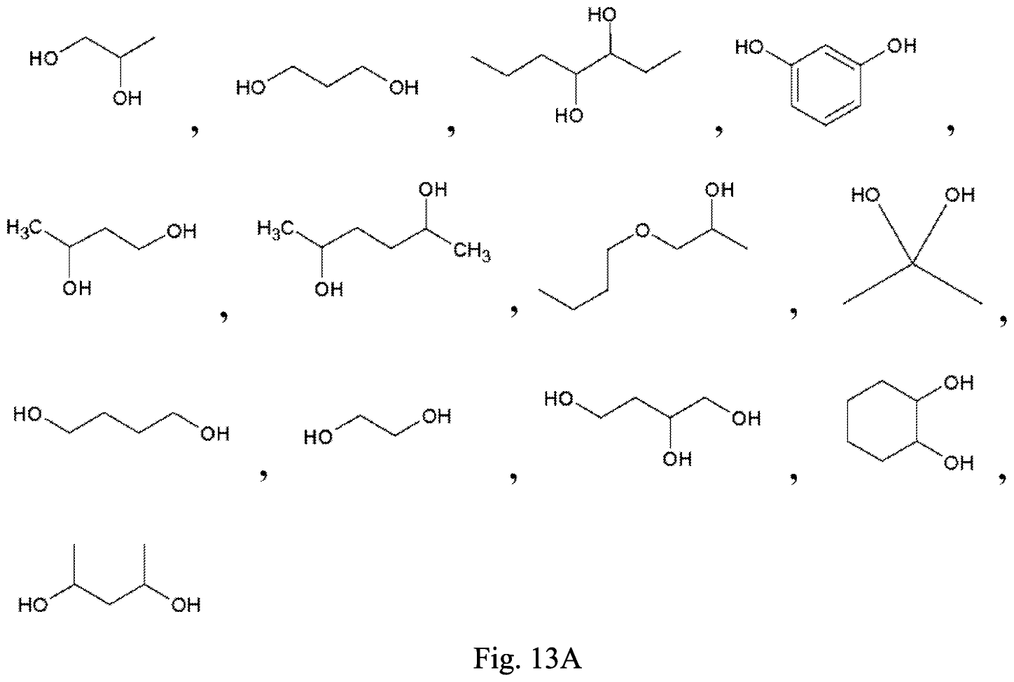

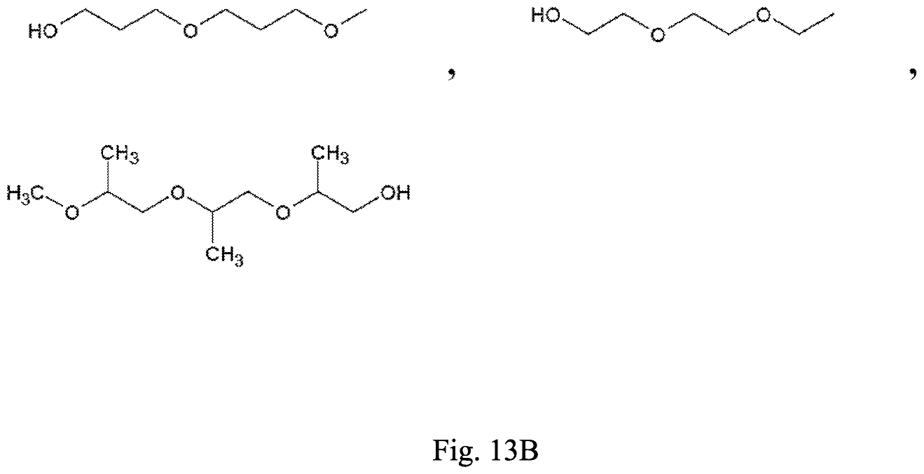

In some other embodiments, the third solvent is selected from a group consisting of diol and alcohol with at least one ether group located on the main chain of the alcohol, and an amount ofthe third solvent is controlled at about 0.01% to 50% based on the weight of the first solvent. If the amount of the third solvent is excessively small (e.g., far lower than 0.01%), the line width roughness (LWR) and defects in the photoresist layer 15 could not be improved effectively. FIG. 13A illustrates some examples ofthe diol according to embodiments ofthe disclosure. FIG. 13B illustrates some examples of the alcohol with at least one ether group located on the main chain according to embodiments ofthe disclosure. Each of the diol and the alcohol with at least one ether group located on the main chain has a carbon number of less than 15 in some embodiments.

In some embodiments where the third solvent is selected from a group consisting of diol and alcohol with at least one ether group located on the main chain of the alcohol, the vapor pressure of a sum of the first solvent and the third solvent is greater than 0.2 kPa at 20° C., which allows rapid removal of the solvent mixture by baking. The sum of the first solvent and the third solvent has a boiling point of less than 300° C. and greater than 25° C., and a melting point of less than 23° C.

Reference is made to FIG. 4. Then the photoresist layer 15 undergoes a first baking operation (or pre-exposure baking) S102 to evaporate an excess portion of the solvent mixture in the photoresist layer 15 in some embodiments. The photoresist layer 15 is baked at a temperature and time sufficient to dry or cure the photoresist layer 15.

FIGS. 5A, 5B and 5C show examples of operations including dispensing/spinning and baking according to embodiments of the disclosure. In FIG. 5A, a photoresist composition PRa having a solvent mixture made of the first solvent and the second solvent is dispensed from a dispenser 20 onto a substrate 13 in operation S100 (see FIG. 3) to form the photoresist layer 15a. In some embodiments, the photoresist composition PRa is spin coated on the substrate 13. After the photoresist composition PRa is dispensed/spinned, the photoresist layer 15a is pre-exposure baked. As shown in FIG. 5A, the metal-containing component of the photoresist layer 15a has a metal core 17 attached/bonded with primary alcohol 19 as its ligands and thus is well-dispersed. By using such configuration, the aggregation of the metal-containing component is decreased, which reduces defects in the photoresist layer 15a and hence improves pattern resolution ofthe photoresist layer 15a. For example, the photoresist layer 15 can reduce the defects by greater than 10% compared to the use of conventional photoresist solvents in some embodiments.

In FIG. 5B, a photoresist composition PRb having a solvent mixture made of the first solvent, the second solvent and the third solvent is dispensed from a dispenser 20 onto a substrate 13 in operation S100 (see FIG. 3) to form the photoresist layer 15b. In some embodiments, the photoresist composition PRb is spin coated on the substrate 13. After the photoresist composition PRb is dispensed/spun, the photoresist layer 15a is pre-exposure baked. The metal-containing component ofthe photoresist layer 15b has a metal core 17 attached/bonded with primary alcohol 19, secondary alcohol 21 and tertiary alcohol 23 as its ligands and thus is well-dispersed. By using such configuration, the aggregation ofthe metal-containing component is decreased, which reduces defects in the photoresist layer 15b and hence improves pattern resolution ofthe photoresist layer 15b.

In FIG. 5C, a photoresist composition PRc having a solvent mixture made of the first solvent, the second solvent and the third solvent is dispensed from a dispenser 20 onto a substrate 13 in operation S100 (see FIG. 3) to form the photoresist layer 15c. In some embodiments, the photoresist composition PRc is spin coated on the substrate 13. After the photoresist composition PRc is dispensed/spun, the photoresist layer 15c is pre-exposure baked. The metal-containing component of the photoresist layer 15c has a metal core 17 attached/bonded with primary alcohol 19 and an alcohol 25 selected from diol or alcohol with at least one ether group located on the main chain as its ligands and thus is well-dispersed. By using such configuration, the aggregation of the metal-containing component is decreased, which reduces defects in the photoresist layer 15c and hence improves pattern resolution ofthe photoresist layer 15c.

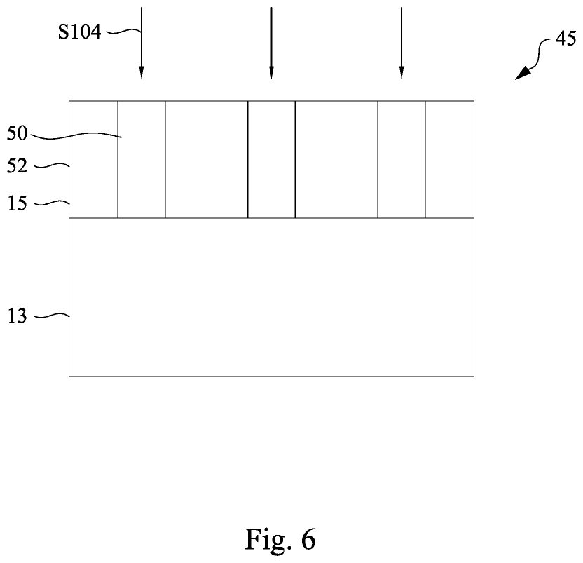

Referring back to FIG. 6, after the first baking operation S102, the photoresist layer 15 is exposed to actinic radiation S104. In some embodiments, the photoresist layer 15 is exposed to ultraviolet radiation. In some embodiments, the ultraviolet radiation is deep ultraviolet radiation (DUV). In some embodiments, the ultraviolet radiation is extreme ultraviolet (EUV) radiation. In some embodiments, the radiation is an electron beam. In some embodiments, an exposure dose of less than 90 mj is sufficient to provide a line width roughness (LWR) of less than 5.0 nm for the photoresist layer 15. The photoresist layer 15 can be applied to patterns to be created that have, for example, pitches smaller than 40 nm.

The region 50 of the photoresist layer 15 exposed to radiation undergoes a chemical reaction thereby changing its solubility in a subsequently applied developer relative to the region 52 of the photoresist layer 15 not exposed to radiation. In some embodiments, the region 50 of the photoresist layer exposed to radiation undergoes a reaction making the exposed portion more soluble in a developer. In other embodiments, the region 50 of the photoresist layer exposed to radiation undergoes a crosslinking reaction making the exposed region 50 less soluble in a developer.

Next, the photoresist layer 15 undergoes a post-exposure bake. The post-exposure baking may be used to assist in the generating, dispersing, and reacting of ions or free radicals generated from the impingement of the radiation upon the photoresist layer 15 during the exposure. Such assistance helps to create or enhance chemical reactions that generate chemical differences between the exposed region 50 and the unexposed region 52 within the photoresist layer 15. These chemical differences also cause differences in the solubility between the exposed region 50 and the unexposed region 52.

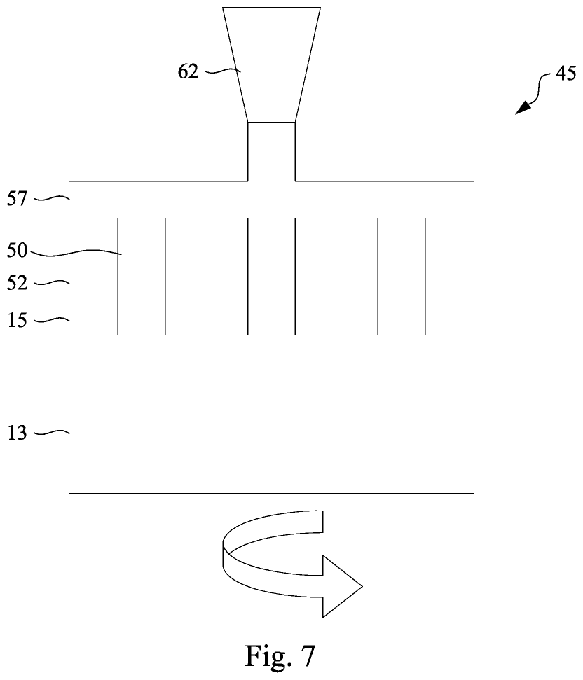

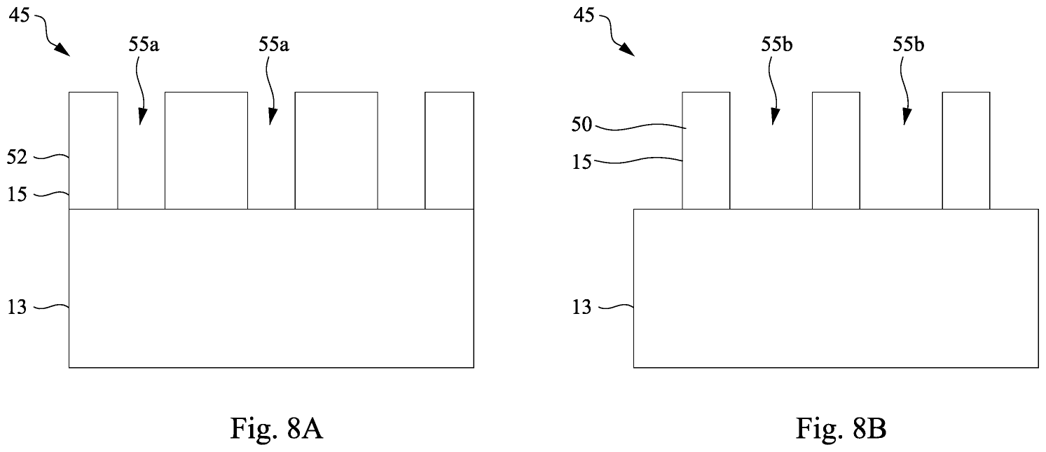

The exposed photoresist layer is subsequently developed by applying a developer to the selectively exposed photoresist layer, as shown in FIG. 7, a developer 57 is supplied from a dispenser 62 to the photoresist layer 15. In some embodiments, the exposed region of the photoresist layer 15 is removed by the developer 57 forming a pattern of openings 55a in the photoresist layer 15 to expose the substrate 13, as shown in FIG. 8A. In other embodiments, the unexposed region of the photoresist layer 52 is removed by the developer 57 forming a pattern of openings 55b in the photoresist layer 15 to expose the substrate 13, as shown in FIG. 8B.

In an alternative embodiment, the first solvent including primary alcohol is added in the developer 57 and the amount of the first solvent is from 100 ppm to 100% based on the weight of the developer 57. Examples of the primary alcohol are shown in FIG. 10. In some other embodiments, the first solvent including primary alcohol and the third solvent selected from a group consisting of secondary alcohol, tertiary alcohol, diol or alcohol with at least one ether group located on the main chain are added in the developer 57. The amount of a sum of the first solvent and the third solvent is from 100 ppm to 100% based on the weight of the developer 57. Examples of the primary alcohol, secondary alcohol, tertiary alcohol, diol or alcohol with at least one ether group located on the main chain are shown in FIGS. 11, 12, 13A and 13B, respectively.

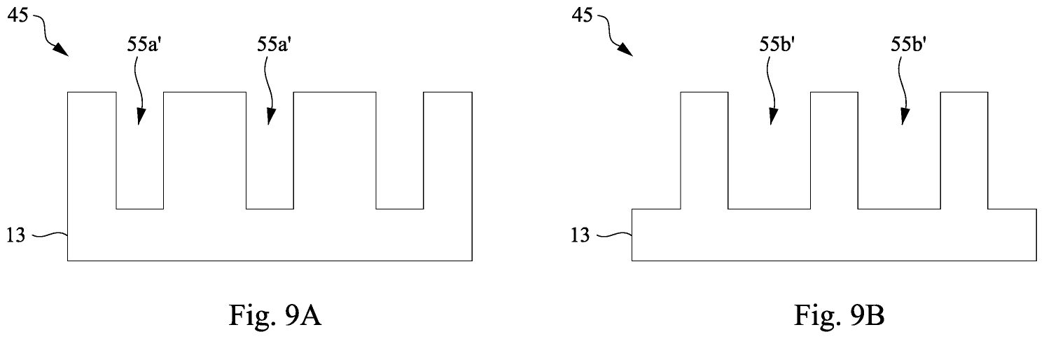

In some embodiments, the pattern of openings 55a, 55b in the photoresist layer 15 are extended into the layer to be patterned or substrate 13 to create a pattern of openings 55a′, 55b′ in the substrate 13, thereby transferring the pattern in the photoresist layer 15 into the substrate 13, as shown in FIGS. 9A and 9B. Due to the reduced defects in the photoresist layer 15, the pattern dimension accuracy of the pattern ofthe substrate 13 can be improved. The pattern is extended into the substrate 13 by etching, using one or more suitable etchants. The remaining photoresist of the regions 50, 52 is at least partially removed during the etching operation in some embodiments. In other embodiments, the remaining photoresist of the regions 50, 52 is removed after etching the substrate 13 by using a suitable photoresist stripper solvent or by a photoresist ashing operation.

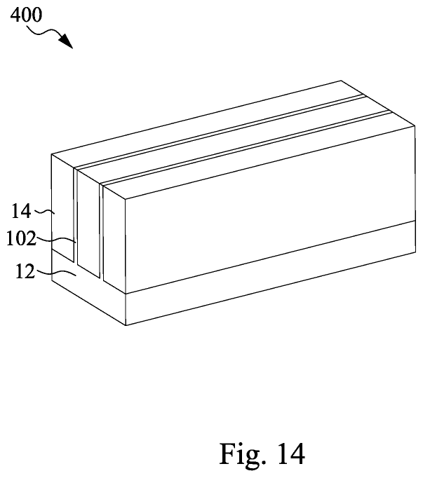

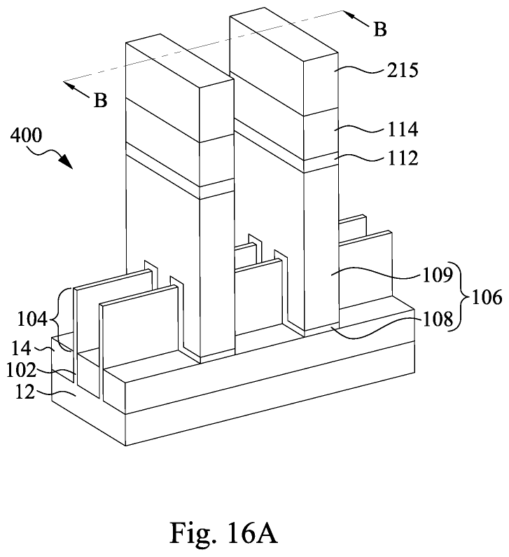

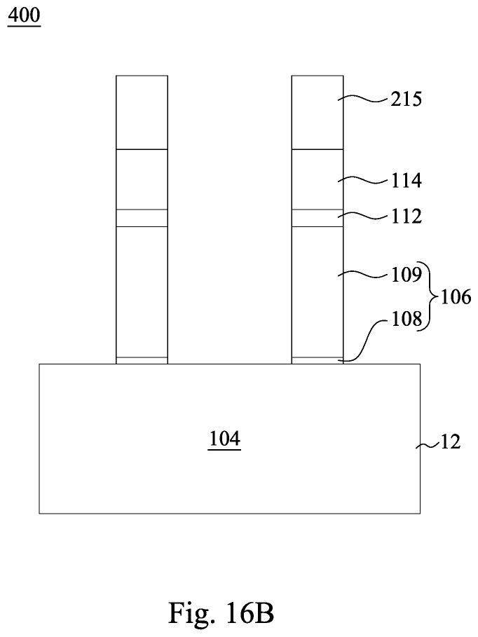

FIGS. 14, 15, 16A illustrate perspective views of additional fabrication processes in the) formation of a semiconductor device 400 on a substrate 12 in accordance with some embodiments of the present disclosure. FIGS. 16B, 17, 18 and 19 illustrate cross-sectional views of additional fabrication processes in the formation of a semiconductor device 400 using a substrate 12 in accordance with some embodiments ofthe present disclosure. Reference is made to FIG. 14. FIG. 14 illustrates a perspective view of an initial structure. The initial structure includes the substrate 12. The substrate 12 is similar to the substrate 13 in terms of composition and formation, such as being patterned by the photoresist layer 15 as discussed previously with respect to FIGS. 3-5C. Isolation regions such as shallow trench isolation (STI) regions 14 may be formed to extend into the substrate 12. The portions of substrate 12 between neighboring STI regions 14 are referred to as semiconductor strips 102. As discussed previously, with reference to FIGS. 8A-8B and 9A-9B, by using the patterned photosensitive layer 15, a pattern dimension accuracy of the the semiconductor strips 102 of the substrate 12 can be improved.

STI regions 14 may include a liner oxide (not shown). The liner oxide may be formed of a thermal oxide formed through a thermal oxidation of a surface layer of the substrate 12. The liner oxide may also be a deposited silicon oxide layer formed using, for example, Atomic Layer Deposition (ALD), High-Density Plasma Chemical Vapor Deposition (HDPCVD), or Chemical Vapor Deposition (CVD). The STI regions 14 may also include a dielectric material over the liner oxide, and the dielectric material may be formed using flowable chemical vapor deposition (FCVD), spin-on coating, or the like.

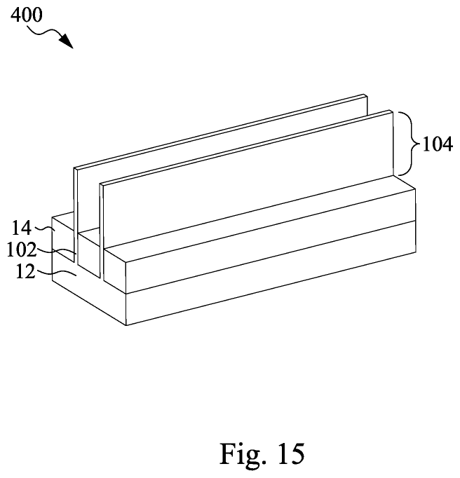

Referring to FIG. 15, the STI regions 14 are recessed, so that the top portions of semiconductor strips 102 protrude higher than the top surfaces ofthe neighboring STI regions 14 to form protruding fins 104. The etching may be performed using a dry etching process or a wet etching process.

The materials of fins 104 may also be replaced with materials different from that of substrate 12. For example, if the fins 104 serve for n-type transistors, protruding fins 104 may be formed of Si, SiP, SIC, SiPC, or a III-V compound semiconductor such as InP, GaAs, AlAs, InAs, InAlAs, InGaAs, or the like. On the other hand, if the fins 104 serve for p-type transistors, the protruding fins 104 may be formed of Si, SiGe, SiGeB, Ge, or a III-V compound semiconductor such as InSb, GaSb, InGaSb, or the like.

Referring to FIGS. 16A and 16B, dummy gate structures 106 are formed on the top surfaces and the sidewalls of fins 104. FIG. 16B illustrates a cross-sectional view obtained from a vertical plane containing line B-B in FIG. 16A. Formation of the dummy gate structures 106 includes depositing in sequence a blankly formed gate dielectric layer and a blankly formed dummy gate electrode layer across the fins 104, followed by patterning the blanket formed gate dielectric layer and the blankly formed dummy gate electrode layer. As a result of the patterning, the dummy gate structure 106 includes a dummy gate dielectric layer 108 and a dummy gate electrode 109 over the dummy gate dielectric layer 108. The dummy gate dielectric layers 108 can be any acceptable dielectric layer, such as silicon oxide, silicon nitride, the like, or a combination thereof, and may be formed using any acceptable process, such as thermal oxidation, a spin process, CVD, or the like. The dummy gate electrodes 109 can be any acceptable electrode layer, such as comprising polysilicon, metal, the like, or a combination thereof The gate electrode layer can be deposited by any acceptable deposition process, such as CVD, plasma enhanced CVD (PECVD), or the like. Each of dummy gate structures 106 crosses over a single one or a plurality of fins 104. Dummy gate structures 106 may have lengthwise directions perpendicular to the lengthwise directions of the respective fins 104.

The blankly formed dummy gate electrode layer and the blankly formed gate dielectric layer may be patterned using a tri-layer structure. Bottom masks 112, top masks 114 and patterned photosensitive layers 215, in which the patterned photosensitive layers 215 is made of a metal-containing component with primary alcohol as ligands, are formed over the blankly formed dummy gate electrode layer in sequence. The above discussion of photoresist layer 15 applies to the patterned photosensitive layers 215, unless mentioned otherwise. By using the photoresist layer 215 as a mask, the pattern dimension accuracy of the underlying layer (e.g., the dummy gate electrodes 109 and the dummy gate dielectric layers 108) can be improved.

In an alternative embodiment, the bottom masks 112 and the top masks 114 are made of one or more layers of SiO₂, SiCN, SiON, Al₂O₃, SiN, or other suitable materials. In certain embodiments, the bottom masks 112 include silicon nitride, and the top masks 114 include silicon oxide.

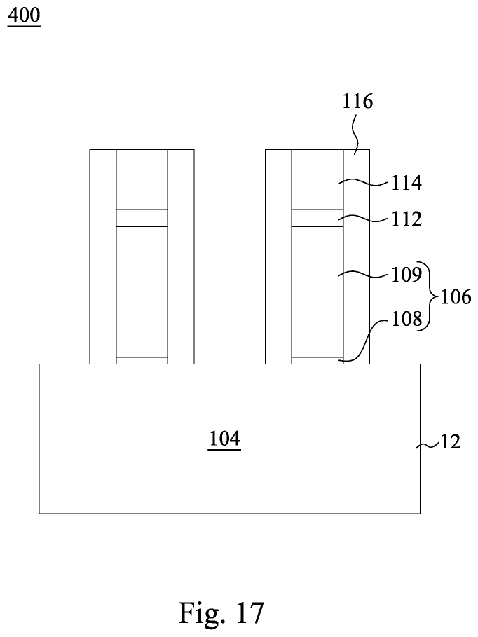

Next, as illustrated in FIG. 17, gate spacers 116 are formed on sidewalls of the dummy gate structures 106. In some embodiments of the gate spacer formation step, a spacer material layer is deposited on the substrate 12. The spacer material layer may be a conformal layer that is subsequently etched back to form gate spacers 116. The spacer material layer is made of a low-k dielectric material. The low-k dielectric material has a dielectric constant (k value) of lower than about 3.5. Suitable materials for the low-k dielectric material may include, but are not limited to, doped silicon dioxide, fluorinated silica glass (FSG), carbon-doped silicon dioxide, porous silicon dioxide, porous carbon-doped silicon dioxide, SiLK™ (an organic polymeric dielectric distributed by Dow Chemical of Michigan), Black Diamond (a product of Applied Materials of Santa Clara, Calif.), Xerogel, Aerogel, amorphous fluorinated carbon, Parylene, bis-benxocyclocutenes (BCB), polyimide, polynoroboneses, benzocyclocutene, PTFE, porous SILK, hydrogen silsesquioxane (HSQ), methylsilsesquioxane (MSQ), and/or combinations thereof. By way of example and not limitation, the spacer material layer may be formed using processes such as, CVD process, a subatmospheric CVD (SACVD) process, a flowable CVD process, an ALD process, a physical vapor deposition (PVD) process, or other suitable process. An anisotropic etching process is then performed on the deposited spacer material layer to expose portions of the fins 104 not covered by the dummy gate structures 106 (e.g., in source/drain regions of the fins 104). Portions of the spacer material layer directly above the dummy gate structures 106 may be completely removed by this anisotropic etching process. Portions of the spacer material layer on sidewalls ofthe dummy gate structures 106 may remain, forming gate spacers, which are denoted as the gate spacers 116, for the sake of simplicity. In some embodiments, the gate spacers 116 may be used to offset subsequently formed doped regions, such as source/drain regions. The gate spacers 116 may further be used for designing or modifying the source/drain region profile.

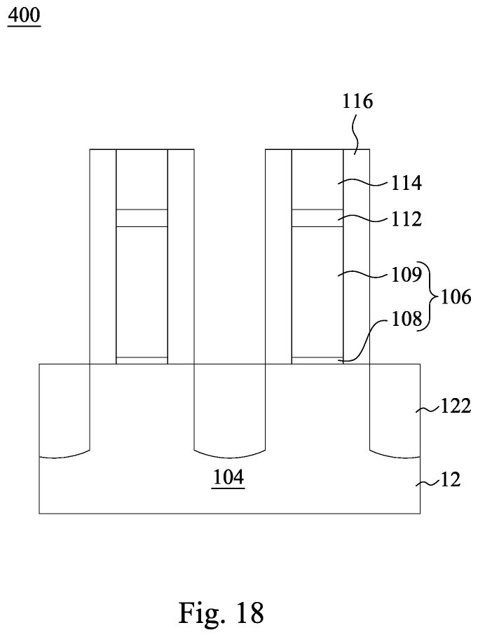

In FIG. 18, after formation of the gate spacers 116 is completed, source/drain epitaxial structures 122 are formed on source/drain regions of the protruding fins 104 that are not covered by the dummy gate structures 106 and the gate spacers 116. In some embodiments, formation of the source/drain epitaxial structures 122 includes recessing source/drain regions of the fin 104, followed by epitaxially growing semiconductor materials in the recessed source/drain regions of the fin 104. The source/drain epitaxial structures 122 are on opposite sides of the dummy gate structure 106.

The source/drain regions of the fins 104 can be recessed using suitable selective etching processing that attacks the fins 104, but hardly attacks the gate spacers 116 and the top masks 114 of the dummy gate structures 106. For example, recessing the fins 104 may be performed by a dry chemical etch with a plasma source and an etchant gas. The plasma source may be inductively coupled plasma (ICR) etch, transformer coupled plasma (TCP) etch, electron cyclotron resonance (ECR) etch, reactive ion etch (RIE), or the like and the etchant gas may be fluorine, chlorine, bromine, combinations thereof, or the like, which etches the protruding fins 104 at a faster etch rate than it etches the gate spacers 116 and the top masks 114 of the dummy gate structures 106. In some other embodiments, recessing the protruding fins 104 may be performed by a wet chemical etch, such as ammonium peroxide mixture (APM), NH₄OH, tetramethylammonium hydroxide (TMAH), combinations thereof, or the like, which etches the fins 104 at a faster etch rate than it etches the gate spacers 116 and the top masks 114 of the dummy gate structures 106. In some other embodiments, recessing the protruding fins 104 may be performed by a combination of a dry chemical etch and a wet chemical etch.

Once recesses are created in the source/drain regions of the fin 104, source/drain epitaxial structures 122 are formed in the source/drain recesses in the fin 104 by using one or more epitaxy or epitaxial (epi) processes that provides one or more epitaxial materials on the protruding fins 104. During the epitaxial growth process, the gate spacers 116 limit the one or more epitaxial materials to source/drain regions in the fin 104. In some embodiments, the lattice constants of the source/drain epitaxial structures 122 are different from the lattice constant of the fins 104, so that the channel region in the fin 104 and between the source/drain epitaxial structures 122 can be strained or stressed by the source/drain epitaxial structures 122 to improve carrier mobility of the semiconductor device and enhance the device performance. The epitaxy processes include CVD deposition techniques (e.g., PECVD, vapor-phase epitaxy (VPE) and/or ultra-high vacuum CVD (UHV-CVD)), molecular beam epitaxy, and/or other suitable processes. The epitaxy process may use gaseous and/or liquid precursors, which interact with the composition of the fins 104.

In some embodiments, the source/drain epitaxial structures 122 may include Ge, Si, GaAs, AlGaAs, SiGe, GaAsP, SiP, or other suitable material. The source/drain epitaxial structures 122 may be in-situ doped during the epitaxial process by introducing doping species including: p-type dopants, such as boron or BF₂; n-type dopants, such as phosphorus or arsenic; and/or other suitable dopants including combinations thereof. If the source/drain epitaxial structures 122 are not in-situ doped, an implantation process (i.e., a junction implant process) is performed to dope the source/drain epitaxial structures 122. In some exemplary embodiments, the source/drain epitaxial structures 122 in an n-type transistor include SiP, while those in a p-type include GeSnB and/or SiGeSnB. In embodiments with different device types, a mask, such as a photoresist, may be formed over n-type device regions, while exposing p-type device regions, and p-type epitaxial structures may be formed on the exposed fins 104 in the p-type device regions. The mask may then be removed. Subsequently, a mask, such as a photoresist, may be formed over the p-type device region while exposing the n-type device regions, and n-type epitaxial structures may be formed on the exposed fins 104 in the n-type device region. The mask may then be removed.

Once the source/drain epitaxial structures 122 are formed, an annealing process can be performed to activate the p-type dopants or n-type dopants in the source/drain epitaxial structures 122. The annealing process may be, for example, a rapid thermal anneal (RTA), a laser anneal, a millisecond thermal annealing (MSA) process or the like.

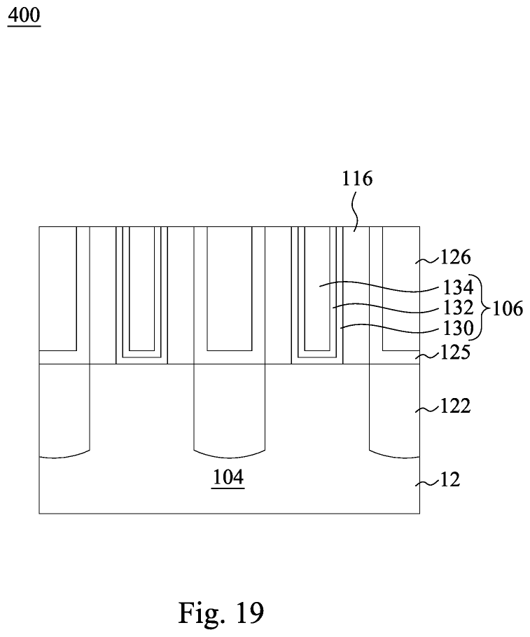

Next, in FIG. 19, a contact etch stop layer (CESL) 125 and an interlayer dielectric (ILD) layer 126 are formed on the substrate 12 in sequence. In some examples, the CESL 125 includes a silicon nitride layer, silicon oxide layer, a silicon oxynitride layer, and/or other suitable materials having a different etch selectivity than the ILD layer 126. The CESL 125 may be formed by plasma-enhanced chemical vapor deposition (PECVD) process and/or other suitable deposition or oxidation processes. In some embodiments, the ILD layer 126 includes materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials having a different etch selectivity than the CESL 125. The ILD layer 126 may be deposited by a PECVD process or other suitable deposition technique. In some embodiments, after formation of the ILD layer 126, the wafer may be subject to a high thermal budget process to anneal the ILD layer 126.

In some examples, after forming the ILD layer 126, a planarization process may be performed to remove excessive materials of the ILD layer 126 and the CESL 125. For example, a planarization process includes a chemical mechanical planarization (CMP) process which removes portions of the ILD layer 126 and the CESL 125 overlying the dummy gate structures 106. In some embodiments, the CMP process also removes bottom masks 112 and top masks 114 (as shown in FIG. 18) and exposes the dummy gate electrodes 109.

An etching process is performed to remove the dummy gate electrode 109 and the dummy gate dielectric layer 108, resulting in gate trenches between corresponding gate spacers 116. The dummy gate structures 106 are removed using a selective etching process (e.g., selective dry etching, selective wet etching, or a combination thereof) that etches materials in the dummy gate structures 106 at a faster etch rate than it etches other materials (e.g., gate spacers 116 and/or the ILD layer 126).

Thereafter, replacement gate structures 128 are respectively formed in the gate trenches. The gate structures 128 may be the final gates of FinFETs. In FinFETs, the fins may be patterned by any suitable method. For example, the fins may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins. The final gate structures each may be a high-k/metal gate (HKMG) stack, however other compositions are possible. In some embodiments, each of the gate structures 128 forms the gate associated with the three-sides of the channel region provided by the fin 104. Stated another way, each of the gate structures 128 wraps around the fin 104 on three sides. In various embodiments, the high-k/metal gate structure 128 includes a gate dielectric layer 130 lining the gate trench, a work function metal layer 132 formed over the gate dielectric layer 130, and a fill metal 134 formed over the work function metal layer 132 and filling a remainder of gate trenches. The gate dielectric layer 130 includes an interfacial layer (e.g., silicon oxide layer) and a high-k gate dielectric layer over the interfacial layer. High-k gate dielectrics, as used and described herein, include dielectric materials having a high dielectric constant, for example, greater than that of thermal silicon oxide (˜3.9). The work function metal layer 132 and/or the fill metal 134 used within high-k/metal gate structures 128 may include a metal, metal alloy, or metal silicide. Formation of the high-k/metal gate structures 128 may include multiple deposition processes to form various gate materials, one or more liner layers, and one or more CMP processes to remove excessive gate materials.

In some embodiments, the interfacial layer of the gate dielectric layer 130 may include a dielectric material such as silicon oxide (SiO₂), HfSiO, or silicon oxynitride (SiON). The interfacial layer may be formed by chemical oxidation, thermal oxidation, atomic layer deposition (ALD), chemical vapor deposition (CVD), and/or other suitable method. The high-k dielectric layer of the gate dielectric layer 130 may include hafnium oxide (HfO₂). Alternatively, the gate dielectric layer 130 may include other high-k dielectrics, such as hafnium silicon oxide (HfSiO), hafnium silicon oxynitride (HfSiON), hafnium tantalum oxide (HfTaO), hafnium titanium oxide (HfTiO), hafnium zirconium oxide (HfZrO), lanthanum oxide (LaO), zirconium oxide (ZrO), titanium oxide (TiO), tantalum oxide (Ta₂O₅), yttrium oxide (Y₂O₃), strontium titanium oxide (SrTiO₃, STO), barium titanium oxide (BaTiO₃, BTO), barium zirconium oxide (BaZrO), hafnium lanthanum oxide (HfLaO), lanthanum silicon oxide (LaSiO), aluminum silicon oxide (AlSiO), aluminum oxide (Al₂O₃), silicon nitride (Si₃N₄), oxynitrides (SiON), and combinations thereof.

The work function metal layer 132 may include work function metals to provide a suitable work function for the high-k/metal gate structures 128. For an n-type FinFET, the work function metal layer 132 may include one or more n-type work function metals (N-metal). The n-type work function metals may exemplarily include, but are not limited to, titanium aluminide (TiAl), titanium aluminium nitride (TiAlN), carbo-nitride tantalum (TaCN), hafnium (Hf), zirconium (Zr), titanium (Ti), tantalum (Ta), aluminum (Al), metal carbides (e.g., hafnium carbide (HfC), zirconium carbide (ZrC), titanium carbide (TiC), aluminum carbide (AlC)), aluminides, and/or other suitable materials. On the other hand, for a p-type FinFET, the work function metal layer 132 may include one or more p-type work function metals (P-metal). The p-type work function metals may exemplarily include, but are not limited to, titanium nitride (TiN), tungsten nitride (WN), tungsten (W), ruthenium (Ru), palladium (Pd), platinum (Pt), cobalt (Co), nickel (Ni), conductive metal oxides, and/or other suitable materials.

In some embodiments, the fill metal 134 may exemplarily include, but are not limited to, tungsten, aluminum, copper, nickel, cobalt, titanium, tantalum, titanium nitride, tantalum nitride, nickel silicide, cobalt silicide, TaC, TaSiN, TaCN, TiAl, TiAlN, or other suitable materials.

In some embodiments, the semiconductor device 400 includes other layers or features not specifically illustrated. In some embodiments, back end of line (BEOL) processes are performed on the semiconductor device 400. In some embodiments, the semiconductor device 400 is formed by a non-replacement metal gate process or a gate-first process.

Based on the above discussions, it can be seen that the present disclosure offers advantages over conventional methods. It is understood, however, that other embodiments may offer additional advantages, and not all advantages are necessarily disclosed herein, and that no particular advantage is required for all embodiments. One advantage is that the aggregation of the metal-containing component is decreased, which reduces defects in the photoresist layer and hence improves pattern resolution of the photoresist layer. Another advantage is that the primary alcohol has a higher environmental stability, for example, the primary alcohol is more resistant toward moisture, water, contaminations with high polarity functional group left from fabrication on the equipment.

In some embodiments, a method of manufacturing a semiconductor device includes forming a photoresist layer over a substrate, exposing the photoresist layer to an EUV radiation, and developing the exposed photoresist layer. The photoresist layer has a composition includes a solvent mixture including a first solvent comprising primary alcohol and a metal-containing component dissolved in the solvent mixture. In some embodiments, the primary alcohol of the first solvent has a carbon number of 8 or less. In some embodiments, the solvent mixture further includes a second solvent including Propylene glycol methyl ether acetate (PGMEA), propylene glycol monomethyl ether (PGME), 1-Ethoxy-2-propanol (PGEE), Gamma-Butyrolactone (GBL), Cyclohexanone (CHN), Ethyl lactate (EL), Methanol, Ethanol, Propanol, n-Butanol, Acetone, Dimethylformamide (DMF), Isopropyl alcohol (IPA), Tetrahydrofuran (THF), Methyl Isobutyl Carbinol (MIBC), (n-butyl acetate (nBA), 2-heptanone (MAK), or a combination thereof. In some embodiments, an amount of the first solvent is within a range from 50% to 100% based on a weight ofthe solvent mixture. In some embodiments, an amount ofthe second solvent is 50% or less than 50% based on a weight of the solvent mixture. In some embodiments, the solvent mixture further includes a third solvent selected from a group consisting of secondary alcohol and tertiary alcohol. In some embodiments, an amount of a sum of the second solvent and the third solvent is 50% or less than 50% based on a weight of the solvent mixture. In some embodiments, the solvent mixture further includes a third solvent selected from a group consisting of diol and alcohol with at least one ether group located on the main chain. In some embodiments, an amount of the third solvent is within 0.01% to 50% based on a weight of the first solvent.

In some embodiments, an extreme ultraviolet lithography (EUVL) method includes turning on a droplet generator to eject a metal droplet toward a zone of excitation in front of a collector, turning on a laser source to emit a laser toward the zone of excitation, such that the metal droplet is heated by the laser to generate EUV radiation, guiding the EUV radiation, by using one or more first optics, toward a reflective mask in an exposure device, and guiding the EUV radiation, by using one or more second optics, reflected from the reflective mask toward a photoresist coated substrate in the exposure device. In some embodiments, the photoresist has a composition comprising a solvent mixture and a metal-containing component dissolved in the solvent mixture. In some embodiments, the solvent mixture includes a first solvent comprising primary alcohol and a second solvent different from the first solvent. In some embodiments, the second solvent includes Propylene glycol methyl ether acetate (PGMEA), propylene glycol monomethyl ether (PGME), 1-Ethoxy-2-propanol (PGEE), Gamma-Butyrolactone (GBL), Cyclohexanone (CHN), Ethyl lactate (EL), Methanol, Ethanol, Propanol, n-Butanol, Acetone, Dimethylformamide (DMF), Isopropyl alcohol (IPA), Tetrahydrofuran (THF), Methyl Isobutyl Carbinol (MIBC), (n-butyl acetate (nBA), 2-heptanone (MAK), or a combination thereof. In some embodiments, the primary alcohol of the first solvent is selected from the following chemical structures:

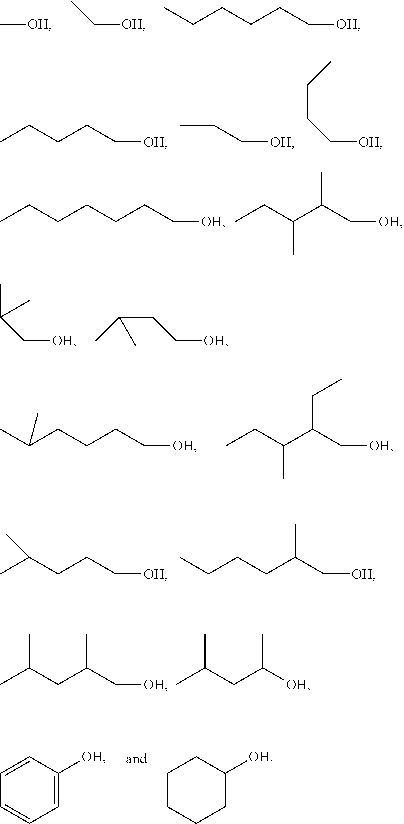

In some embodiments, the solvent mixture further comprises a third solvent different from the first solvent and the second solvent, and the third solvent is selected from the following chemical structures:

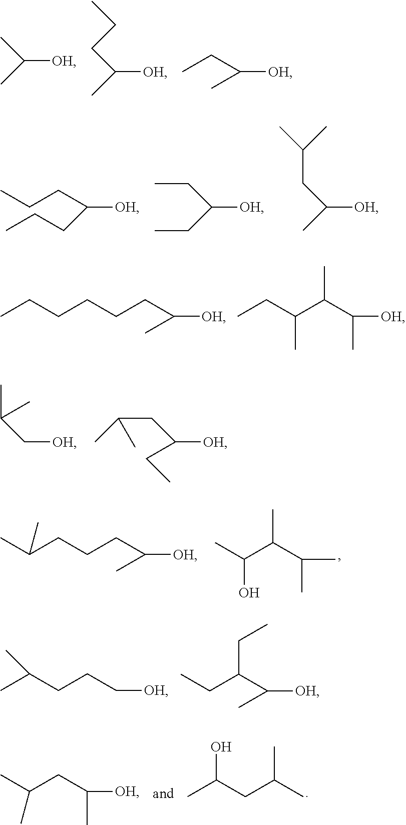

The solvent mixture further comprises a third solvent different from the first solvent and the second solvent, and the third solvent is selected from the following chemical structures:

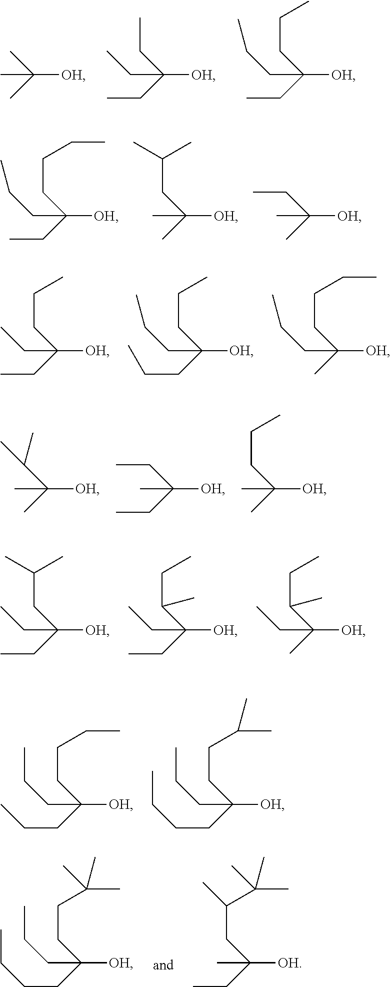

The solvent mixture further comprises a third solvent different from the first solvent and the second solvent, and the third solvent is selected from the following chemical structures:

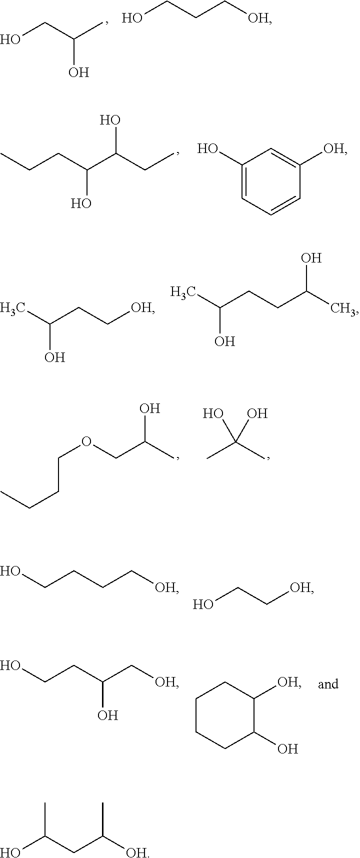

In some embodiments, a photoresist includes a solvent mixture and a metal-containing component dissolved in the solvent mixture. The solvent mixture includes a first solvent comprising primary alcohol and a second solvent different from the first solvent. In some embodiments, a vapor pressure of the first solvent is greater than 0.2 kPa at 20° C. In some embodiments, the solvent mixture further comprises a third solvent, and the third solvent comprises a secondary alcohol, a tertiary alcohol, or a combination thereof In some embodiments, a vapor pressure of a sum ofthe first solvent and the third solvent is greater than 0.2 kPa at 20° C. In some embodiments, the second solvent comprises: Propylene glycol methyl ether acetate (PGMEA), propylene glycol monomethyl ether (PGME), 1-Ethoxy-2-propanol (PGEE), Gamma-Butyrolactone (GBL), Cyclohexanone (CHN), Ethyl lactate (EL), Methanol, Ethanol, Propanol, n-Butanol, Acetone, Dimethylformamide (DMF), Isopropyl alcohol (IPA), Tetrahydrofuran (THF), Methyl Isobutyl Carbinol (MIBC), (n-butyl acetate (nBA), 2-heptanone (MAK), or a combination thereof.

The foregoing outlines features of several embodiments or examples so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments or examples introduced herein. Those skilled in the art should also realize that such equivalent constructions do not depart from the spirit and scope of the present disclosure, and that they may make various changes, substitutions, and alterations herein without departing from the spirit and scope ofthe present disclosure.

What is claimed is:

1. A method of manufacturing a semiconductor device, comprising:
forming a photoresist layer over a substrate;
exposing the photoresist layer to an EUV radiation; and
developing the exposed photoresist layer,
wherein the photoresist layer has a composition comprises:
a solvent mixture comprising:
a first solvent comprising primary alcohol; and
a metal-containing component dissolved in the solvent mixture.

2. The method of claim 1, wherein the primary alcohol of the first solvent has a carbon number of 8 or less.

3. The method of claim 2, wherein the solvent mixture further comprises:
a second solvent comprising Propylene glycol methyl ether acetate (PGMEA), propylene glycol monomethyl ether (PGME), 1-Ethoxy-2-propanol (PGEE), Gamma-Butyrolactone (GBL), Cyclohexanone (CHN), Ethyl lactate (EL), Methanol, Ethanol, Propanol, n-Butanol, Acetone, Dimethylformamide (DMF), Isopropyl alcohol (IPA), Tetrahydrofuran (THF), Methyl Isobutyl Carbinol (MIBC), (n-butyl acetate (nBA), 2-heptanone (MAK), or a combination thereof.

4. The method of claim 3, wherein an amount ofthe first solvent is within a range from 50% to 100% based on a weight ofthe solvent mixture.

5. The method of claim 3, wherein an amount of the second solvent is 50% or less than 50% based on a weight of the solvent mixture.

6. The method of claim I , wherein the solvent mixture further comprises:
a third solvent selected from a group consisting of secondary alcohol and tertiary'alcohol.

7. The method of claim 6, wherein an amount of a sum of the second solvent and the third solvent is 50% or less than 50% based on a weight of the solvent mixture.

8. The method of claim 1, wherein the solvent mixture further comprises:
a third solvent selected from a group consisting of diol and alcohol with at least one ether group located on the main chain.

9. The method of claim 8, wherein an amount ofthe third solvent is within 0.01% to 50% based on a weight ofthe first solvent.

10. An extreme ultraviolet lithography (EUVL) method, comprising:
turning on a droplet generator to eject a metal droplet toward a zone of excitation in front of a collector;
turning on a laser source to emit a laser toward the zone of excitation, such that the metal droplet is heated by the laser to generate EUV radiation;
guiding the EUV radiation, by using one or more first optics, toward a reflective mask in an exposure device; and
guiding the EUV radiation, by using one or more second optics, reflected from the reflective mask toward a photoresist coated substrate in the exposure device,
wherein the photoresist has a composition comprising:
a solvent mixture comprising:
a first solvent comprising primary alcohol; and
a second solvent different from the first solvent; and
a metal-containing component dissolved in the solvent mixture.

11. The method of claim 10, wherein the second solvent comprises:
Propylene glycol methyl ether acetate (PGMEA), propylene glycol monomethyl ether (PGME), 1-Ethoxy-2-propanol (PGEE), Gamma-Butyrolactone (GBL), Cyclohexanone (CHN), Ethyl lactate (EL), Methanol, Ethanol, Propanol, n-Butanol, Acetone, Dimethylformamide (DMF), Isopropyl alcohol (IPA), Tetrahydrofuran (THF), Methyl Isobutyl Carbinol (MIBC), (n-butyl acetate (nBA), 2-heptanone (MAK), or a combination thereof.

12. The method of claim 10, wherein the primary alcohol of the first solvent is selected from the following chemical structures:

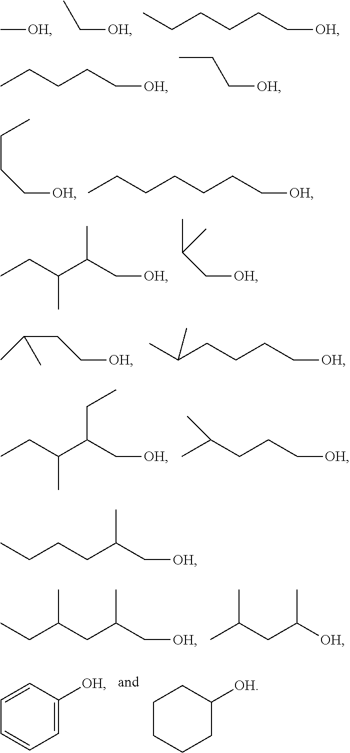

13. The method of claim 10, wherein the solvent mixture further comprises a third solvent different from the first solvent and the second solvent, and the third solvent is selected from the following chemical structures:

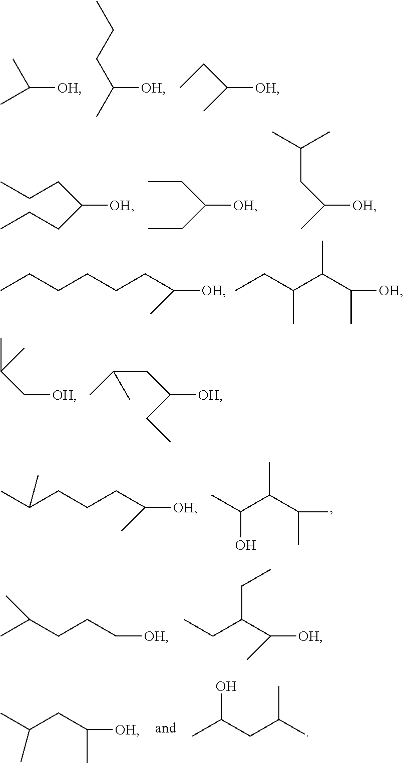

14. The method of claim 10, wherein the solvent mixture further comprises a third solvent different from the first solvent and the second solvent, and the third solvent is selected from the following chemical structures:

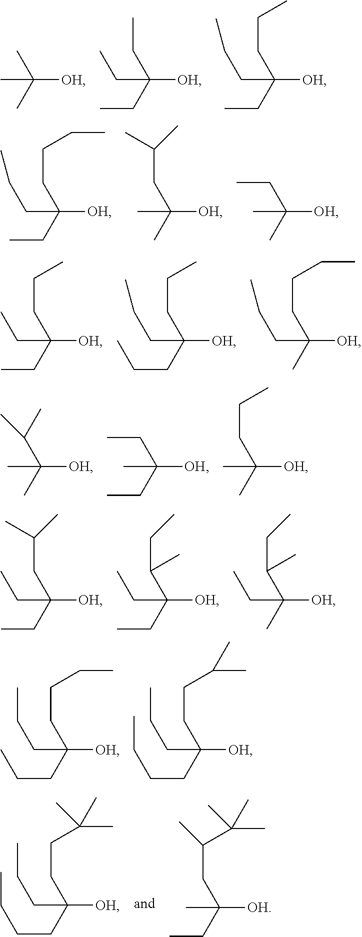

15. The method of claim 10, wherein the solvent mixture further comprises a third solvent different from the first solvent and the second solvent, and the third solvent is selected from the following chemical structures:

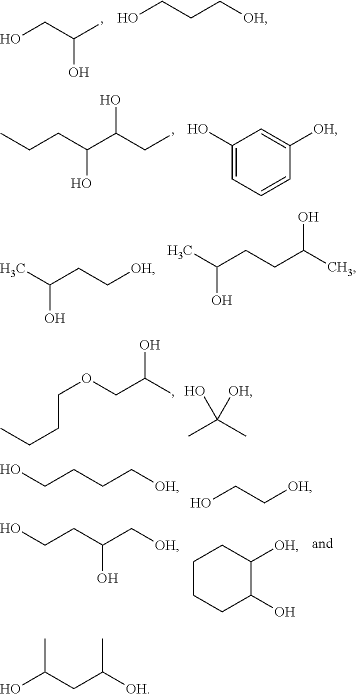

16. A photoresist, comprising:
a solvent mixture, wherein the solvent mixture comprises:
a first solvent comprising primary alcohol; and
a second solvent different from the first solvent; and
a metal-containing component dissolved in the solvent mixture.

17. The photoresist of claim 16, wherein a vapor pressure of the first solvent is greater than 0.2 kPa at 20° C.

18. The photoresist of claim 16, wherein the solvent mixture further comprises a third solvent, and the third solvent comprises a secondary alcohol, a tertiary alcohol, or a combination thereof.

19. The photoresist of claim 16, wherein a vapor pressure of a sum of the first solvent and the third solvent is greater than 0.2 kPa at 20° C.

20. The photoresist of claim 16, wherein the second solvent comprises:
Propylene glycol methyl ether acetate (PGMEA), propylene glycol monomethyl ether (PGME), 1-Ethoxy-2-propanol (PGEE), Gamma-Butyrolactone (GBL), Cyclohexanone (CHN), Ethyl lactate (EL), Methanol, Ethanol, Propanol, n-Butanol, Acetone, Dimethylformamide (DMF), Isopropyl alcohol (IPA), Tetrahydrofuran (THF), Methyl Isobutyl Carbinol (MIBC), (n-butyl acetate (nBA), 2-heptanone (MAK), or a combination thereof.
